(19) United States
(12) Patent Application Publication
(10) Pub. No.: US 2025/0311524 A1
(43) Pub. Date: Oct. 2, 2025

(54) DETECTION DEVICE

(71) Applicant: Japan Display Inc., Tokyo (JP)

(72) Inventor: Genki ASOZU, Tokyo (JP)

(21) Appl. No.: 19/085,186

(22) Filed: Mar. 20, 2025

(30) Foreign Application Priority Data
Mar. 26, 2024 (JP) 2024-049210

(51) Int. Cl. H10K 39/32; G06V 40/13

(52) U.S. Cl. CPC H10K 39/32; G06V 40/1318

(57) ABSTRACT

According to an aspect, a detection device includes: a substrate; photodiodes in each of which a lower electrode, a lower buffer layer, an active layer, an upper buffer layer, and an upper electrode are stacked; drive transistors corresponding to the photodiodes; and a gate line coupled to gates of the drive transistors. The photodiodes includes a first photodiode and a second photodiode arranged in the first direction. The first photodiode is configured to be driven in a reverse bias state and the second photodiode is configured to be driven in a forward bias state during a first period in which an output of the first photodiode is detected. The second photodiode is configured to be driven in the reverse bias state and the first photodiode is configured to be driven in the forward bias state during a second period in which an output of the second photodiode is detected.

### CROSS-REFERENCE TO RELATED APPLICATION

This application claims the benefit of priority from Japanese Patent Application No. 2024-049210 filed on Mar. 26, 2024, the entire contents of which are incorporated herein by reference.

### BACKGROUND

### 1. Technical Field

What is disclosed herein relates to a detection device.

### 2. Description of the Related Art

Japanese Patent Application Laid-open Publication No. 2011-010054 (JP-A-2011-010054) describes a detection device (photoelectric conversion device in JP-A-2011-010054) using a photoelectric conversion element that generates a signal electric charge corresponding to incident light. An organic photodiode (OPD) in which an organic semiconductor material is used as an active layer is known as such a photoelectric conversion element.

In detection devices using the OPD, occurrence of variations in characteristics of the organic semiconductor layer may reduce detection accuracy.

### SUMMARY

According to an aspect, a detection device includes: a substrate; a plurality of photodiodes in each of which a lower electrode, a lower buffer layer, an active layer, an upper buffer layer, and an upper electrode are stacked on the substrate in the order as listed; a plurality of drive transistors corresponding to the photodiodes; and a gate line that is coupled to gates of the drive transistors and extends in a first direction. The photodiodes includes a first photodiode and a second photodiode that are arranged adjacent to each other in the first direction. The first photodiode is configured to be driven in a reverse bias state and the second photodiode is configured to be driven in a forward bias state during a first period in which an output of the first photodiode is detected. The second photodiode is configured to be driven in the reverse bias state and the first photodiode is configured to be driven in the forward bias state during a second period in which an output of the second photodiode is detected.

### BRIEF DESCRIPTION OF THE DRAWINGS

FIG. 1 is a plan view schematically illustrating a detection device according to a first embodiment;

FIG. 2 is a block diagram illustrating a configuration example of the detection device according to the first embodiment;

FIG. 3 is a plan view schematically illustrating an arrangement relation between a plurality of photodiodes in a detection area, and insulating films and a sealing film in a peripheral area;

FIG. 4 is a sectional view along IV-IV′ of FIG. 3;

FIG. 5 is a circuit diagram illustrating the detection device according to the first embodiment;

FIG. 6 is an explanatory diagram for explaining drive patterns of a plurality of sensor pixels according to the first embodiment;

FIG. 7 illustrates explanatory diagrams for explaining a relation between a reverse bias voltage that is supplied to the photodiodes and photodiode characteristics;

FIG. 8 is a sectional view schematically illustrating the adjacent photodiodes PD;

FIG. 9 is an explanatory diagram for explaining the drive patterns of the sensor pixels according to a second embodiment;

FIG. 10 is an explanatory diagram for explaining the drive patterns of the sensor pixels according to a third embodiment; and

FIG. 11 is an explanatory diagram for explaining the drive patterns of the sensor pixels according to a fourth embodiment.

### DETAILED DESCRIPTION

The following describes modes (embodiments) for carrying out the present disclosure in detail with reference to the drawings. The present disclosure is not limited to the description of the embodiments given below. Components described below include those easily conceivable by those skilled in the art or those substantially identical thereto. In addition, the components described below can be combined as appropriate. What is disclosed herein is merely an example, and the present disclosure naturally encompasses appropriate modifications easily conceivable by those skilled in the art while maintaining the gist of the present disclosure. To further clarify the description, the drawings may schematically illustrate, for example, widths, thicknesses, and shapes of various parts as compared with actual aspects thereof. However, they are merely examples, and interpretation of the present disclosure is not limited thereto. The same component as that described with reference to an already mentioned drawing is denoted by the same reference numeral through the present disclosure and the drawings, and detailed description thereof may not be repeated where appropriate.

In the present specification and claims, in expressing an aspect of disposing another structure on or above a certain structure, a case of simply expressing “on” includes both a case of disposing the other structure immediately on the certain structure so as to contact the certain structure and a case of disposing the other structure above the certain structure with still another structure interposed therebetween, unless otherwise specified.

### First Embodiment

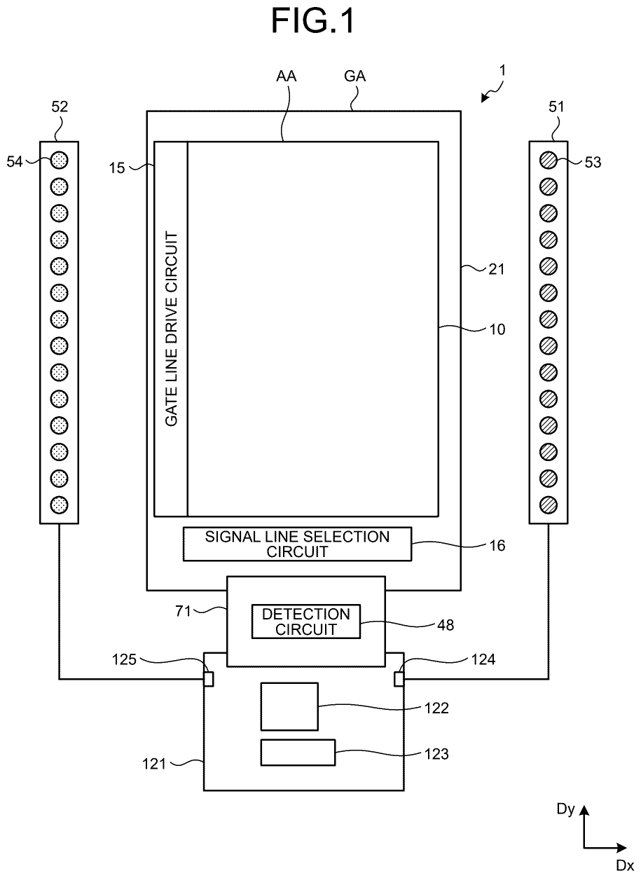

FIG. 1 is a plan view schematically illustrating a detection device according to a first embodiment. As illustrated in FIG. 1, a detection device 1 includes a substrate 21, a sensor 10, a gate line drive circuit 15, a signal line selection circuit 16, a detection circuit 48, a control circuit 122, a power supply circuit 123, a first light source base member 51, a second light source base member 52, and light sources 53 and 54. The first light source base member 51 is provided with a plurality of the light sources 53. The second light source base member 52 is provided with a plurality of the light sources 54.

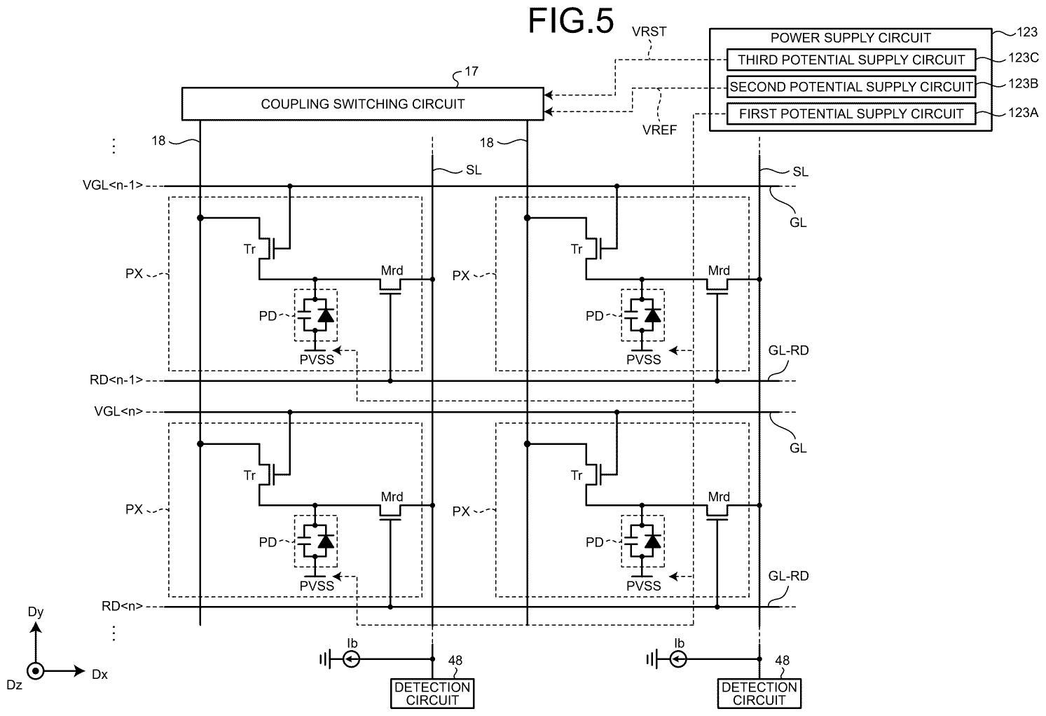

The substrate 21 is electrically coupled to a control substrate 121 through a wiring substrate 71. The wiring substrate 71 is, for example, a flexible printed circuit board or a rigid circuit board. The wiring substrate 71 is provided with the detection circuit 48. The control substrate 121 is provided with the control circuit 122 and the power supply circuit 123. The control circuit 122 is a field-programmable gate array (FPGA), for example. The control circuit 122 supplies control signals to the sensor 10, the gate line drive circuit 15, and the signal line selection circuit 16 to control detection operations of the sensor 10. The control circuit 122 supplies control signals to the light sources 53 and 54 to control lighting or non-lighting of the light sources 53 and 54. The power supply circuit 123 supplies voltage signals including, for example, a power supply potential PVSS (refer to FIG. 5) to the sensor 10, the gate line drive circuit 15, and the signal line selection circuit 16. The power supply circuit 123 supplies a power supply voltage to the light sources 53 and 54.

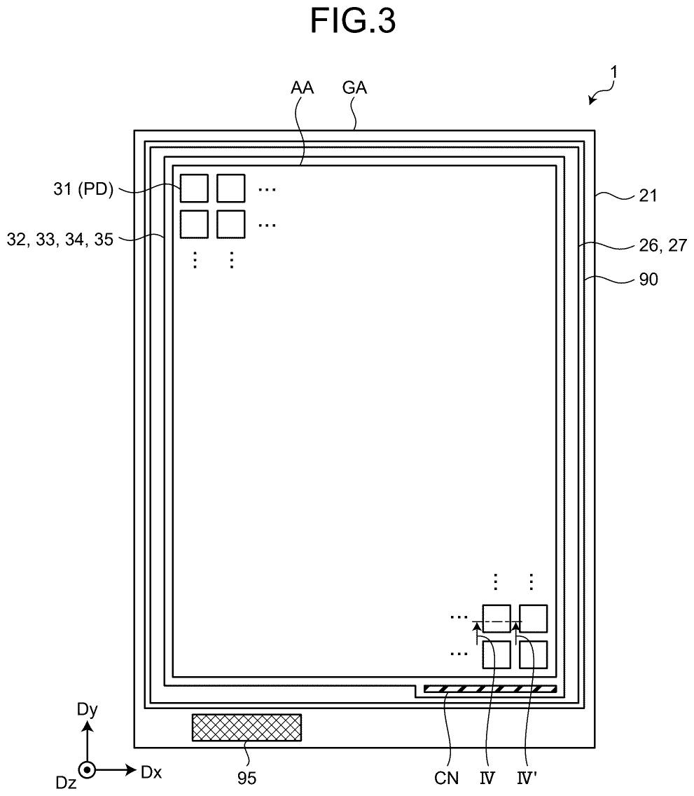

The substrate 21 has a detection area AA and a peripheral area GA. The detection area AA is an area provided with a plurality of photodiodes PD (refer to FIG. 3) included in the sensor 10. The peripheral area GA is an area between the outer perimeter of the detection area AA and the outer edges of the substrate 21, and is an area not provided with the photodiodes PD.

The gate line drive circuit 15 and the signal line selection circuit 16 are provided in the peripheral area GA. Specifically, the gate line drive circuit 15 is provided in an area extending along a second direction Dy in the peripheral area GA. The signal line selection circuit 16 is provided in an area extending along a first direction Dx in the peripheral area GA, and is provided between the sensor 10 and the detection circuit 48.

In the following description, the first direction Dx is a direction in a plane parallel to the substrate 21. The second direction Dy is a direction in the plane parallel to the substrate 21 and is a direction orthogonal to the first direction Dx. The second direction Dy may, however, non-orthogonally intersect the first direction Dx. A third direction Dz is a direction orthogonal to the first direction Dx and the second direction Dy and is a direction normal to the main surface of the substrate 21. The term “plan view” refers to a positional relation when viewed in a direction orthogonal to the substrate 21.

The light sources 53 are provided on the first light source base member 51, and are arranged along the second direction Dy. The light sources 54 are provided on the second light source base member 52, and are arranged along the second direction Dy. The first light source base member 51 and the second light source base member 52 are electrically coupled to the control circuit 122 and the power supply circuit 123 through respective terminals 124 and 125 provided on the control substrate 121.

For example, inorganic light-emitting diodes (LEDs) or organic electroluminescent (EL) diodes (organic light-emitting diodes (OLEDs)) are used as the light sources 53 and 54. The light sources 53 and 54 emit light having different wavelengths from each other.

First light emitted from the light sources 53 is mainly reflected on a surface of an object to be detected, such as a finger, and enters the sensor 10. As a result, the sensor 10 can detect a fingerprint by detecting a shape of asperities on the surface of the finger or the like. Second light emitted from the light sources 54 is mainly reflected in the finger or the like, or transmitted through the finger or the like, and enters the sensor 10. As a result, the sensor 10 can detect information on a living body in the finger or the like. Examples of the information on the living body include, but are not limited to, pulse waves, pulsation, and a vascular image of the finger or a palm. That is, the detection device 1 may be configured as a fingerprint detection device to detect the fingerprint or a vein detection device to detect a vascular pattern of, for example, veins.

The arrangement of the light sources 53 and 54 illustrated in FIG. 1 is merely an example, and can be changed as appropriate. The detection device 1 is provided with a plurality of types of the light sources 53 and 54 as light sources. However, the light sources are not limited thereto, and may be of one type. For example, the light sources 53 and 54 may be arranged on each of the first and the second light source base members 51 and 52. The light sources 53 and 54 may be provided on one light source base member, or three or more light source base members. Alternatively, only at least one light source needs to be disposed.

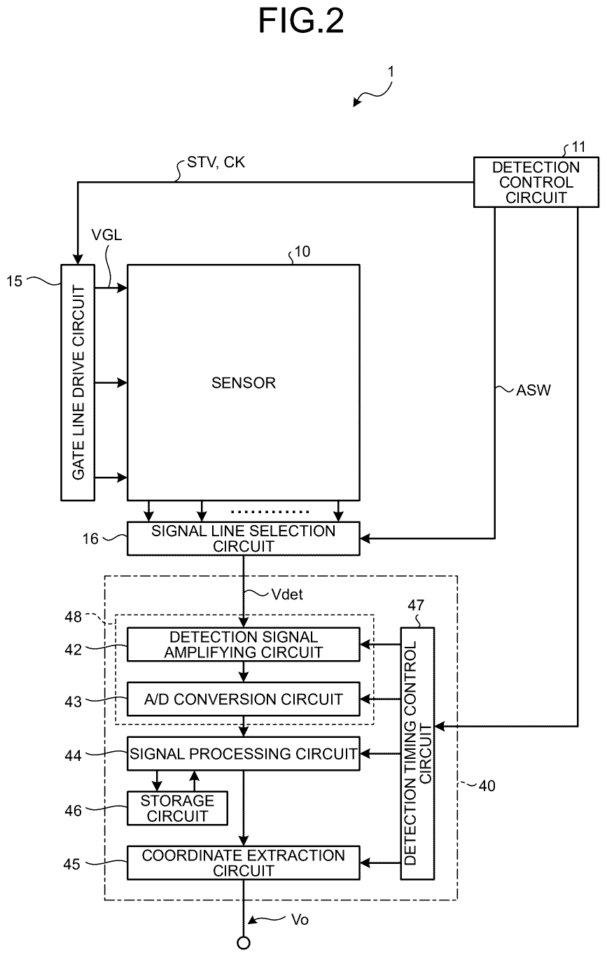

FIG. 2 is a block diagram illustrating a configuration example of the detection device according to the first embodiment. As illustrated in FIG. 2, the detection device 1 further includes a detection control circuit 11 and a detector 40. The control circuit 122 includes one, some, or all functions of the detection control circuit 11. The control circuit 122 also includes one, some, or all functions of the detector 40 other than those of the detection circuit 48.

The sensor 10 includes the photodiodes PD. Each of the photodiodes PD included in the sensor 10 outputs an electrical signal corresponding to light irradiating the photodiode PD as a detection signal Vdet to the signal line selection circuit 16. The sensor 10 performs the detection in response to a gate drive signal VGL supplied from the gate line drive circuit 15.

The detection control circuit 11 is a circuit that supplies respective control signals to the gate line drive circuit 15, the signal line selection circuit 16, and the detector 40 to control operations of these components. The detection control circuit 11 supplies various control signals including, for example, a start signal STV and a clock signal CK to the gate line drive circuit 15. The detection control circuit 11 also supplies various control signals including, for example, a selection signal ASW to the signal line selection circuit 16. The detection control circuit 11 also supplies various control signals to the light sources 53 and 54 to control the lighting and non-lighting of the respective light sources 53 and 54.

The gate line drive circuit 15 is a circuit that drives a plurality of gate lines GL (refer to FIG. 5) based on the various control signals. The gate line drive circuit 15 sequentially or simultaneously selects the gate lines GL and supplies the gate drive signals VGL to the selected gate lines GL. By this operation, the gate line drive circuit 15 selects the photodiodes PD coupled to the gate lines GL.

The signal line selection circuit 16 is a switch circuit that sequentially or simultaneously selects a plurality of signal lines SL (refer to FIG. 5). The signal line selection circuit 16 is a multiplexer, for example. The signal line selection circuit 16 couples the selected signal lines SL to the detection circuit 48 based on the selection signal ASW supplied from the detection control circuit 11. Through this operation, the signal line selection circuit 16 outputs the detection signal Vdet of the photodiode PD to the detector 40.

The detector 40 includes the detection circuit 48, a signal processing circuit 44, a coordinate extraction circuit 45, a storage circuit 46, and a detection timing control circuit 47. The detection timing control circuit 47 controls the detection circuit 48, the signal processing circuit 44, and the coordinate extraction circuit 45 to operate these circuits synchronously based on a control signal supplied from the detection control circuit 11.

The detection circuit 48 is an analog front-end (AFE) circuit, for example. The detection circuit 48 is a signal processing circuit having functions of at least a detection signal amplifying circuit 42 and an analog-to-digital (A/D) conversion circuit 43. The detection signal amplifying circuit 42 amplifies the detection signal Vdet. The A/D conversion circuit 43 converts analog signals output from the detection signal amplifying circuit 42 into digital signals.

The signal processing circuit 44 is a logic circuit that detects predetermined physical quantities received by the sensor 10 based on output signals of the detection circuit 48. The signal processing circuit 44 can detect the asperities on the surface of the finger or the palm based on the signals from the detection circuit 48 when the finger is in contact with or in proximity to a detection surface. The signal processing circuit 44 can detect the information on the living body based on the signals from the detection circuit 48. Examples of the information on the living body include, but are not limited to, the vascular image, the pulse waves, the pulsation, and a blood oxygen level of the finger or the palm.

The storage circuit 46 temporarily stores therein signals calculated by the signal processing circuit 44. The storage circuit 46 may be, for example, a random-access memory (RAM) or a register circuit.

The coordinate extraction circuit 45 is a logic circuit that obtains detected coordinates of the asperities on the surface of the finger or the like when the contact or proximity of the finger is detected by the signal processing circuit 44. The coordinate extraction circuit 45 is the logic circuit that also obtains detected coordinates of blood vessels in the finger or the palm. The coordinate extraction circuit 45 combines the detection signals Vdet output from the photodiodes PD of the sensor 10 to generate two-dimensional information indicating the shape of the asperities on the surface of the finger or the like and two-dimensional information indicating the shape of the blood vessels in the finger or the palm. The coordinate extraction circuit 45 may output the detection signals Vdet as sensor output voltages Vo instead of calculating the detected coordinates.

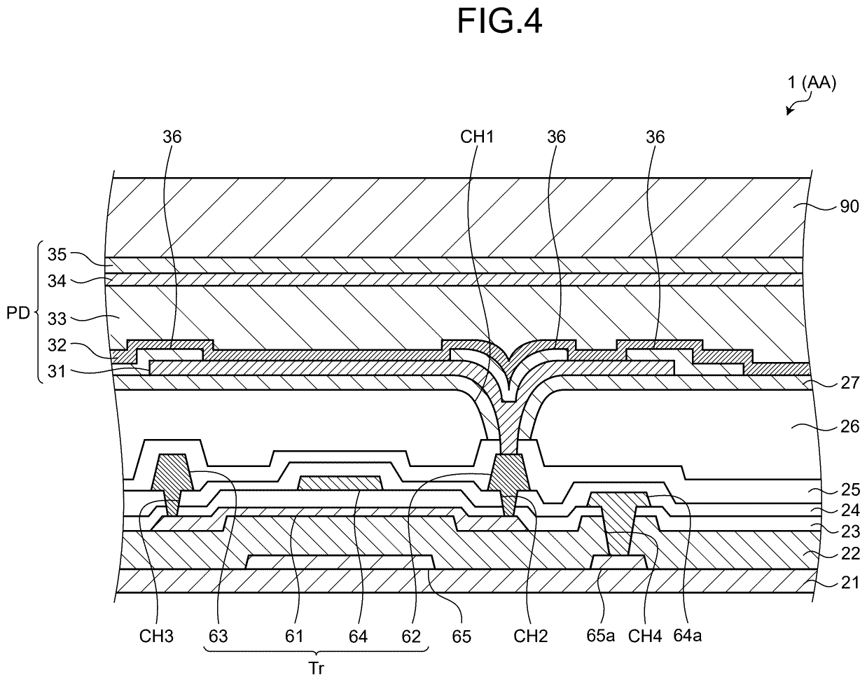

The following describes a configuration of the photodiodes PD with reference to FIGS. 3 and 4. FIG. 3 is a plan view schematically illustrating an arrangement relation between the photodiodes in the detection area, and insulating films and a sealing film in the peripheral area. FIG. 4 is a sectional view along IV-IV′ of FIG. 3.

As illustrated in FIG. 3, the photodiodes PD are arranged in a matrix having a row-column configuration in the detection area AA. As illustrated in FIGS. 3 and 4, the photodiodes PD each include a lower electrode 31, a lower buffer layer 32, an active layer 33, an upper buffer layer 34, and an upper electrode 35. A plurality of the lower electrodes 31 are provided so as to be separated from each other and correspond to the photodiodes PD, and arranged in a matrix having a row-column configuration in the detection area AA. The lower buffer layer 32, the active layer 33, the upper buffer layer 34, and the upper electrode 35 are continuously provided across the photodiodes PD and are provided over the entire detection area AA. A portion of the upper electrode 35 extends into the peripheral area GA, is coupled to a contact portion CN, and is electrically coupled to external circuitry (such as the control circuit 122 and the power supply circuit 123 (refer to FIG. 1)) through wiring of the substrate 21.

The detection device 1 includes a sealing film 90 covering the photodiodes PD. The sealing film 90 is provided over the detection area AA and the peripheral area GA and provided to outer edge sides of the substrate 21. The sealing film 90 extends to further outer edge sides of the substrate 21 than a plurality of insulating films (for example, an organic insulating film 26, a barrier film 27, and the like) provided on the substrate 21. The sealing film 90 can reduce moisture entering the detection area AA from the outer edge sides of the substrate 21.

A mounting portion 95 is provided on the substrate 21, outside the outer perimeter of the sealing film 90. The mounting portion 95 includes, for example, a coupling terminal for coupling to the wiring substrate 71 (refer to FIG. 1). Alternatively, the mounting portion 95 may include mounting terminals for mounting integrated circuits (ICs) included in the detection circuit 48 and the like.

The following describes a multilayered structure of the photodiodes PD and the sealing film 90 of the detection device 1. In the following description, a direction from the substrate 21 toward the sealing film 90 in a direction orthogonal to a surface of the substrate 21 is referred to as “upper side” or simply “above”. A direction from the sealing film 90 toward the substrate 21 is referred to as “lower side” or simply “below”.

As illustrated in FIG. 4, the detection device 1 includes the substrate 21, a drive transistor Tr, a plurality of inorganic insulating films (undercoat film 22, gate insulating film 23, interlayer insulating film 24, and overlay insulating film 25), the organic insulating film 26, the barrier film 27, the photodiode PD, and the sealing film 90. In the detection area AA, the inorganic insulating films (undercoat film 22, gate insulating film 23, interlayer insulating film 24, and overlay insulating film 25), the organic insulating film 26, the barrier film 27, the photodiode PD, and the sealing film 90 are stacked in this order on the substrate 21.

The substrate 21 is an insulating substrate formed of a film-like resin. The drive transistor Tr is provided in an area overlapping the lower electrode 31 of the photodiode PD. Specifically, the drive transistor Tr includes a semiconductor layer 61, a source electrode 62, a drain electrode 63, and a gate electrode 64.

A light-blocking film 65 is provided on the substrate 21. The light-blocking film 65 is provided between the semiconductor layer 61 and the substrate 21. The light-blocking film 65 reduces light entering a channel region of the semiconductor layer 61 from the substrate 21 side.

The undercoat film 22 is provided on the substrate 21 so as to cover the light-blocking film 65. The undercoat film 22 is formed, for example, of an inorganic insulating film such as a silicon nitride film or a silicon oxide film. The configuration of the undercoat film 22 is not limited to that illustrated in FIG. 4. For example, the undercoat film 22 may be a multilayered film having two, three, or more layers.

The drive transistor Tr is provided above the substrate 21. The semiconductor layer 61 is provided on the undercoat film 22. The gate insulating film 23 is provided on the undercoat film 22 so as to cover the semiconductor layer 61. The gate insulating film 23 is, for example, an inorganic insulating film such as a silicon oxide film. The gate electrode 64 is provided on the gate insulating film 23.

In the example illustrated in FIG. 4, the drive transistor Tr has a top-gate structure. However, the drive transistor Tr is not limited thereto and may have a bottom-gate structure, or a dual-gate structure in which the gate electrodes 64 are provided on the upper and lower sides of the semiconductor layer 61.

The interlayer insulating film 24 is provided on the gate insulating film 23 so as to cover the gate electrode 64. The interlayer insulating film 24 has, for example, a multilayered structure of a silicon nitride film and a silicon oxide film. The source electrode 62 and the drain electrode 63 are provided on the interlayer insulating film 24. The source electrode 62 is coupled to a source region of the semiconductor layer 61 through a contact hole CH2 provided through the gate insulating film 23 and the interlayer insulating film 24. The drain electrode 63 is coupled to a drain region of the semiconductor layer 61 through a contact hole CH3 provided through the gate insulating film 23 and the interlayer insulating film 24. The overlay insulating film 25 is provided on the interlayer insulating film 24 so as to cover the source electrode 62 and the drain electrode 63.

Coupling wiring 64a is provided in the same layer as the gate electrode 64. The coupling wiring 64a is electrically coupled to the gate electrode 64. Coupling wiring 65a is provided in the same layer as the light-blocking film 65. The coupling wiring 65a is electrically coupled to the light-blocking film 65. The coupling wiring 64a is coupled to the coupling wiring 65a through a contact hole CH4 penetrating the undercoat film 22 and the gate insulating film 23. As a result, the light-blocking film 65 is electrically coupled to the gate electrode 64 via the coupling wiring 64a and 65a and is supplied with the same potential as that of the gate electrode 64.

The organic insulating film 26 is provided on the overlay insulating film 25 so as to cover the source electrode 62 and the drain electrode 63 of the drive transistor Tr. The organic insulating film 26 is a planarizing film formed of an organic insulating material. In the present embodiment, a contact hole CH1 in the organic insulating film 26 is provided in an area thereof overlapping the source electrode 62. The lower electrode 31 of the photodiode PD is electrically coupled to the source electrode 62 at the bottom of the contact hole CH1.

The detection device 1 may have a configuration in which the overlay insulating film 25 among the inorganic insulating films (undercoat film 22, gate insulating film 23, interlayer insulating film 24, and overlay insulating film 25) is not provided. In that case, the organic insulating film 26 is provided on the interlayer insulating film 24 so as to cover the source electrode 62 and the drain electrode 63.

The barrier film 27 is provided on the organic insulating film 26. The barrier film 27 is formed, for example, of an inorganic insulating material such as a silicon nitride film (SiN).

The photodiode PD is provided on the barrier film 27. In the photodiode PD, the lower electrode 31, the lower buffer layer 32, the active layer 33, the upper buffer layer 34, and the upper electrode 35 are stacked in this order in the direction orthogonal to the substrate 21. The photodiode PD of the present embodiment is an organic photodiode (OPD) using an organic semiconductor as the active layer 33.

The lower electrode 31 is formed, for example, of a light-transmitting conductive material such as indium tin oxide (ITO). The lower buffer layer 32, the active layer 33, the upper buffer layer 34, and the upper electrode 35 are provided continuously across the photodiodes PD. Specifically, the lower buffer layer 32, the active layer 33, the upper buffer layer 34, and the upper electrode 35 are provided so as to overlap the lower electrodes 31 and the barrier film 27 located between the adjacent lower electrodes 31.

An insulating film 36 is provided so as to cover the peripheries of the lower electrode 31. The insulating film 36 is provided so as to cover the contact hole CH1, and covers the lower electrode 31 in an area overlapping the contact hole CH1. The insulating film 36 insulates between the lower electrodes 31 of the adjacent photodiodes PD. Even if a step break occurs in the lower buffer layer 32 in the area overlapping the contact hole CH1, the occurrence of a short circuit between the active layer 33 and the lower electrode 31 can be prevented or reduced because the insulating film 36 is provided. In the present embodiment, the insulating film 36 is formed of an inorganic insulating material such as silicon nitride film (SiN) or silicon oxide film (SiO₂).

The active layer 33 changes in characteristics (for example, voltage-current characteristics and resistance value) according to light emitted thereto. An organic material is used as a material of the active layer 33. Specifically, the active layer 33 has a bulk heterostructure containing a mixture of a p-type organic semiconductor and an n-type fullerene derivative ((6,6)-phenyl-C₆₁-butyric acid methyl ester (PCBM)) that is an n-type organic semiconductor. As the active layer 33, low-molecular-weight organic materials can be used including, for example, fullerene (C₆₀), phenyl-C₆₁-butyric acid methyl ester (PCBM), copper phthalocyanine (CuPc), fluorinated copper phthalocyanine (F₁₆CuPc), 5,6,11,12-tetraphenyltetracene (rubrene), and perylene diimide (PDI) (derivative of perylene).

The active layer 33 can be formed by a vapor deposition process (dry process) using any of the low-molecular-weight organic materials listed above. In this case, the active layer 33 may be, for example, a multilayered film of CuPc and F₁₆CuPc, or a multilayered film of rubrene and C₆₀. The active layer 33 can also be formed by a coating process (wet process). In this case, the active layer 33 is made using a material obtained by combining any of the above-listed low-molecular-weight organic materials with a high-molecular-weight organic material. As the high-molecular-weight organic material, for example, poly(3-hexylthiophene) (P3HT) and F8-alt-benzothiadiazole (F8BT) can be used. The active layer 33 can be a film made of a mixture of P3HT and PCBM, or a film made of a mixture of F8BT and PDI. The active layer 33 is not limited to the bulk heterostructure and may have a positive-intrinsic-negative (PIN) structure.

The lower buffer layer 32 and the upper buffer layer 34 are provided to facilitate holes and electrons generated in the active layer 33 to reach the lower electrode 31 or the upper electrode 35. The lower buffer layer 32 is provided between the lower electrode 31 and the active layer 33 and is in direct contact with the lower electrode 31 and the active layer 33. The lower buffer layer 32 is provided between the adjacent lower electrodes 31 so as to cover the barrier film 27.

The upper buffer layer 34 is provided between the active layer 33 and the upper electrode 35 and is in direct contact with the active layer 33 and the upper electrode 35. The upper electrode 35 is provided on the upper buffer layer 34. The upper electrode 35 is formed, for example, of a light-transmitting conductive material such as ITO or indium zinc oxide (IZO). The upper electrode 35 is not limited thereto, and may be formed of, for example, a non-light-transmitting conductive material such as silver (Ag).

In the present embodiment, the lower electrode 31 is a cathode electrode of the photodiode PD, and the upper electrode 35 is an anode electrode of the photodiode PD. In this case, the lower buffer layer 32 is an electron transport layer and the upper buffer layer 34 is a hole transport layer. Polyethylenimine ethoxylated (PEIE) is used as a material of the electron transport layer. The material of the hole transport layer is a metal oxide layer. Tungsten oxide (WO₃), molybdenum oxide, or the like is used as the metal oxide layer.

The lower electrode 31 may be the anode electrode of the photodiode PD, and the upper electrode 35 may be the cathode electrode of the photodiode PD. In that case, the lower buffer layer 32 may be a hole transport layer, and the upper buffer layer 34 may be an electron transport layer.

The sealing film 90 is provided on the upper electrode 35. The sealing film 90 is formed, for example, of an inorganic insulating material such as a silicon nitride film (SiN). The sealing film 90 well seals the photodiode PD, and thus can reduce moisture entering the photodiode PD from the upper surface side thereof. The sealing film 90 is not limited to a single-layer film and may be a multilayered film. The sealing film 90 may have multiple layers including one or more inorganic sealing films formed of an inorganic insulating material and one or more organic sealing films formed of an organic insulating material.

FIG. 5 is a circuit diagram illustrating the detection device according to the first embodiment. As illustrated in FIG. 5, a sensor pixel PX includes the photodiode PD, the drive transistor Tr, and a readout transistor Mrd. A capacitive element (sensor capacitance) is coupled in parallel to the photodiode PD. The capacitive element of the photodiode PD includes capacitance generated, for example, between the lower electrode 31 and the upper electrode 35.

FIG. 5 illustrates two gate lines GL arranged in the second direction Dy among the gate lines GL. FIG. 5 also illustrates two signal lines SL arranged in the first direction Dx among the signal lines SL. The sensor pixel PX is an area surrounded by the gate lines GL and the signal lines SL.

The detection device 1 further includes a coupling switching circuit 17, potential supply lines 18, and readout control scan lines GL-RD. The signal lines SL and the potential supply lines 18 each extend in the second direction Dy and are arranged in the first direction Dx. The gate lines GL and the readout control scan lines GL-RD each extend in the first direction Dx and are arranged in the second direction Dy.

The drive transistors Tr are provided corresponding to the photodiodes PD. The drive transistor Tr is configured as a thin-film transistor, and in this example, configured as an n-channel metal oxide semiconductor (MOS) thin-film transistor (TFT).

Each of the gate lines GL is coupled to the gates of the drive transistors Tr arranged in the first direction Dx. Each of the potential supply lines 18 is coupled to either the sources or the drains of the drive transistors Tr arranged in the second direction Dy. The others of the sources and the drains of the drive transistors Tr are coupled to the cathodes of the photodiodes PD and the readout transistors Mrd.

The anode of the photodiode PD is supplied with the power supply potential PVSS (first potential) from the power supply circuit 123 (first potential supply circuit 123A). The cathode of the photodiode PD is supplied with a refresh potential VREF (second potential) or a reset potential VRST (third potential) from the power supply circuit 123 via the drive transistor Tr, the potential supply line 18, and the coupling switching circuit 17.

More specifically, the potential supply lines 18 are coupled to the power supply circuit 123 via the coupling switching circuit 17. The coupling switching circuit 17 is a switch circuit that sequentially or simultaneously selects the potential supply lines 18. The coupling switching circuit 17 is a multiplexer, for example. Based on a control signal from the control circuit 122, the coupling switching circuit 17 couples a normally driven sensor pixel PX to a third potential supply circuit 123C of the power supply circuit 123. The normally driven sensor pixel PX is the sensor pixel PX to detect the object to be detected, among the sensor pixels PX arranged in the first direction Dx.

This coupling operation supplies the reset potential VRST (third potential) to the cathode of the photodiode PD included in the normally driven sensor pixel PX. The reset potential VRST is higher than the power supply potential PVSS. As a result, the photodiode PD included in the normally driven sensor pixel PX is driven in a reverse bias state. The power supply potential PVSS is set to 0.75 V, for example. The reset potential VRST is set to 2.75 V, for example. In this case, the photodiode PD is supplied with a reverse bias voltage of 2.0 V.

Based on a control signal from the control circuit 122, the coupling switching circuit 17 couples a refresh-driven sensor pixel PX to a second potential supply circuit 123B of the power supply circuit 123. The refresh-driven sensor pixel PX is the sensor pixel PX to be refresh-driven, among the sensor pixels PX arranged in the first direction Dx. In the present disclosure, “refresh driving” or “refresh operation” refers to an operation to return the state of the characteristics of the OPD to an initial state by applying a forward bias current to the photodiode PD.

As a result, the refresh potential VREF (second potential) is supplied to the cathode of the photodiode PD included in the refresh-driven sensor pixel PX. The refresh potential VREF is lower than the power supply potential PVSS. As a result, the photodiode PD included in the refresh-driven sensor pixel PX is driven in a forward bias state. The refresh potential VREF is set to −1.25 V, for example. In this case, a forward bias voltage of 2.0 V is supplied to the photodiode PD.

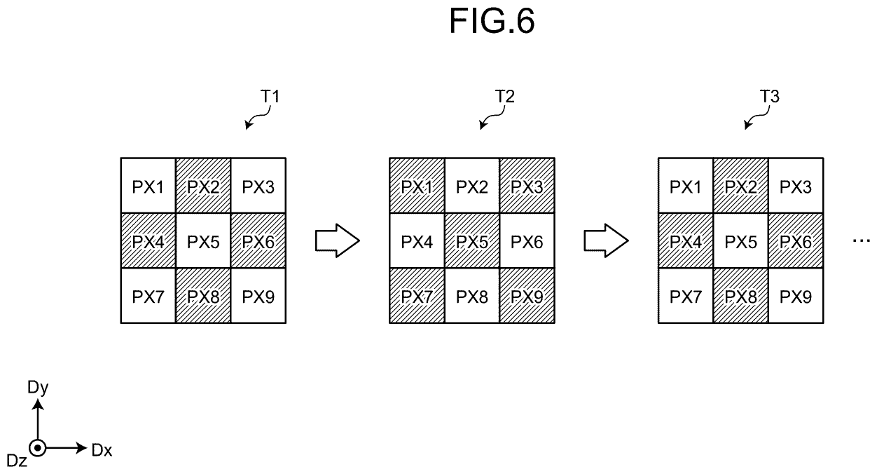

Drive patterns of the normally driven sensor pixels PX and the refresh-driven sensor pixels PX can be switched therebetween for each of the sensor pixels PX arranged in the first direction Dx and for each of the sensor pixels PX arranged in the second direction Dy by operations of the gate line drive circuit 15 (refer to FIG. 1) and the coupling switching circuit 17. The drive patterns of the sensor pixels PX of the present embodiment will be described later with reference to FIG. 6.

Each of the readout control scan lines GL-RD is coupled to the gates of a plurality of the readout transistors Mrd arranged in the first direction Dx. The cathodes of the photodiodes PD are coupled to either of the sources or the drains of the readout transistors Mrd. The others of the sources and the drains of the readout transistors Mrd are coupled to the signal lines SL.

The detection circuit 48 is coupled to a constant current source to apply a bias current Ib to the readout transistors Mrd. This configuration allows an output of each of the sensor pixels PX to be detected via the readout transistor Mrd during a readout period. This constant current source may be provided in the detection circuit 48 or in the peripheral area GA of the substrate 21.

The gate line drive circuit 15 sequentially controls the gate drive signals VGL<n> to a high potential “H” (hereinafter also referred to as “H-control”) during a reset period. As a result, the drive transistor Tr of each of the sensor pixels PX is controlled to be on, and the sensor pixels PX arranged in the row direction are selected. In the normally driven sensor pixel PX among the selected sensor pixels PX, the reset potential VRST is supplied to the cathode of the photodiode PD via the drive transistor Tr. As a result, the photodiode PD is reversely biased. At this time, the photodiode PD is charged according to the reverse bias voltage.

During a refresh period that overlaps the reset period, the refresh potential VREF is supplied to the cathode of photodiode PD via the drive transistor Tr in the refresh-driven sensor pixel PX among the sensor pixels PX selected in response to the gate drive signals VGL<n>. As a result, the photodiode PD is forward biased.

When the gate drive signals VGL<n> are controlled to a low potential “L” (hereinafter, also referred to as “L-control”), the drive transistor Tr of each of the sensor pixels PX is controlled to be off, and an exposure period for each of the photodiodes PD starts in the normally driven sensor pixels PX. During this exposure period, a backward current flows through the photodiode PD, so that the electric charge stored in the photodiode PD during the reset period gradually decreases. The backward current that flows during the exposure period depends on the amount of light entering the photodiode PD.

The gate line drive circuit 15 then sequentially controls readout signals RD<n> to a high potential “H” in the readout period. As a result, the readout transistor Mrd of each of the sensor pixels PX is controlled to be on to cause the bias current Ib to flow, and a voltage corresponding to the electric charge stored in the photodiode PD is detected by the detection circuit 48. The signal line SL corresponding to the refresh-driven sensor pixel PX is decoupled from the detection circuit 48 by the signal line selection circuit 16 (refer to FIG. 1).

The pixel circuit of the sensor pixel PX illustrated in FIG. 5 is merely an example and can be changed as appropriate. The drive transistor Tr is not limited to the n-type TFT and may be configured as a p-type TFT. The sensor pixel PX may be provided with three or more transistors correspondingly to one photodiode PD.

FIG. 6 is an explanatory diagram for explaining the drive patterns of the sensor pixels according to the first embodiment. The following describes the drive patterns of the sensor pixels PX (sensor pixel PX1, sensor pixel PX2, . . . , sensor pixel PX9) in three rows and three columns with reference to FIG. 6. In FIG. 6, the sensor pixel PX not shaded with hatching represents the normally driven sensor pixel PX. The sensor pixel PX shaded with hatching represents the refresh-driven sensor pixel PX.

While FIG. 6 illustrates the sensor pixels PX in three rows and three columns for ease of understanding, a first period T1, a second period T2, and a third period T3 illustrated in FIG. 6 each correspond to a period in which scanning is performed from the sensor pixels PX in the first row to the sensor pixels PX in the last row provided in the detection area AA, and thus, the detection is performed for one frame. Although not illustrated in FIG. 6, the photodiode PD, the drive transistor Tr, the readout transistor Mrd, and various types of wiring as described above are provided in each of the sensor pixels PX.

As illustrated in FIG. 6, the sensor pixels PX1, PX2, and PX3 are arranged in the first direction Dx in the first row. The sensor pixels PX4, PX5, and PX6 are arranged in the first direction Dx in the second row. The sensor pixels PX7, PX8, and PX9 are arranged in the first direction Dx in the third row.

During the first period T1, the refresh-driven sensor pixels PX (photodiodes PD driven in the forward bias state) and the normally driven sensor pixels PX (photodiodes PD driven in the reverse bias state) are alternately arranged in the first direction Dx and alternately arranged in the second direction Dy. Specifically, during the first period T1, the photodiodes PD included in the sensor pixels PX1, PX3, PX5, PX7, and PX9 are driven in the reverse bias state, and the output from each of the photodiodes PD in the sensor pixels PX1, PX3, PX5, PX7, and PX9 is detected. During the first period T1, the photodiodes PD included in the sensor pixels PX2, PX4, PX6, and PX8 are driven in the forward bias state, and each of the photodiodes PD in the sensor pixels PX2, PX4, PX6, and PX8 is refreshed.

Also, during the second period T2, the refresh-driven sensor pixels PX (photodiodes PD driven in the forward bias state) and the normally driven sensor pixels PX (photodiodes PD driven in the reverse bias state) are alternately arranged in the first direction Dx and alternately arranged in the second direction Dy. However, during the second period T2, the drive patterns of the refresh-driven sensor pixels PX and the normally driven sensor pixels PX are inverted with respect to the drive patterns during the first period T1.

Specifically, during the second period T2, the photodiodes PD included in the sensor pixels PX2, PX4, PX6, and PX8 are driven in the reverse bias state, and the output from each of the photodiodes PD in the sensor pixels PX2, PX4, PX6, and PX8 is detected. During the second period T2, the photodiodes PD included in the sensor pixels PX1, PX3, PX5, PX7, and PX9 are driven in the forward bias state, and each of the photodiodes PD in the sensor pixels PX1, PX3, PX5, PX7, and PX9 is refreshed.

When the third period T3 starts, the drive pattern returns to the same drive pattern as during the first period T1. That is, during the third period T3, the drive patterns of the refresh-driven sensor pixels PX (photodiodes PD driven in the forward bias state) and the normally driven sensor pixels PX (photodiodes PD driven in the reverse bias state) are inverted with respect to the drive patterns during the second period T2.

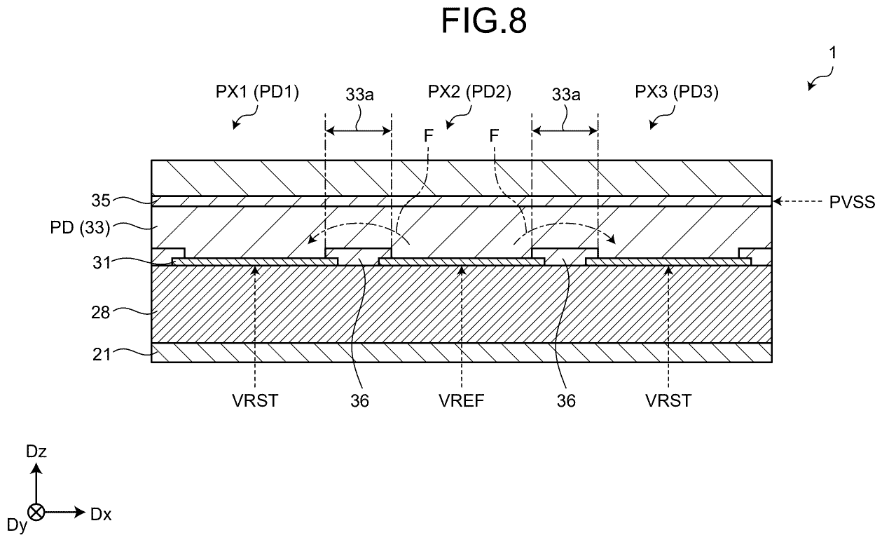

The following describes the details of the drive pattern, for example, focusing on the sensor pixels PX1 and PX2 adjacent to each other in the first direction Dx in the first row among the sensor pixels PX in three rows and three columns. During the first period T1 in which an output of a first photodiode PD1 (refer to FIG. 8) included in the sensor pixel PX1 is detected, a first photodiode PD1 is driven in the reverse bias state, and a second photodiode PD2 included in the sensor pixel PX2 (refer to FIG. 8) is driven in the forward bias state. During the second period T2 in which an output of the second photodiode PD2 is detected, the second photodiode PD2 is driven in the reverse bias state, and the first photodiode PD1 is driven in the forward bias state.

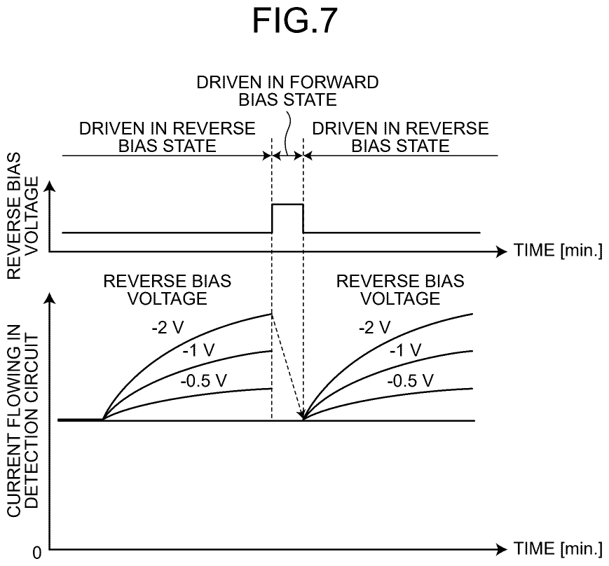

FIG. 7 illustrates explanatory diagrams for explaining a relation between the reverse bias voltage that is supplied to the photodiode and photodiode characteristics. The upper figure of FIG. 7 is a graph schematically illustrating a relation between the reverse bias voltage that is supplied to the photodiode PD and time, and the lower figure of FIG. 7 is a graph schematically illustrating a relation between a current that flows in the detection circuit 48 (dark current output from the photodiode PD) and time.

As illustrated in FIG. 7, when the photodiode PD is driven in the reverse bias state for a predetermined period, carriers trapped in defective portions are accumulated and emitted, and the dark current flowing in the photodiode PD varies (hereinafter, referred to as “change over time of the characteristics of the photodiode PD”). As a result, the value detected by the detection circuit 48 also varies. When the photodiode PD is driven in the forward bias state, the change over time of the characteristics of the photodiode PD is refreshed and the characteristics are returned to the initial state.

As described above, in the detection device 1 of the present embodiment, the normally driven sensor pixels PX and the refresh-driven sensor pixels PX are alternately arranged in the first direction Dx and the second direction Dy during the same period, and each of the sensor pixels PX is driven such that the drive patterns of the normal driving and the refresh driving are inverted every period. As a result, the characteristics of the photodiode PD of each of the sensor pixels PX are returned to the initial state by the refresh driving. This operation can reduce the change over time of the characteristics of the photodiode PD that occurs when the photodiode PD is driven in the reverse bias state for a long time. Therefore, the detection device 1 can reduce the decrease in the detection accuracy.

In the present embodiment, the ratio of the number of the normally driven sensor pixels PX to the number of all the sensor pixels PX in each period is 1/2, and thus, the resolution is 1/2 the resolution in a case where all the sensor pixels PX are used for the detection. The refresh driving of the photodiode PD is performed in synchronization with the detection drive of the photodiode PD. Therefore, the detection device 1 can perform the refresh driving of the photodiode PD without reducing the frame rate of the detection. In the present embodiment, since the normal driving and the refresh driving can be performed for each of the sensor pixels PX, the detection device 1 can improve the flexibility of the drive patterns of the normally driven sensor pixels PX and the refresh-driven sensor pixels PX. For example, the detection device 1 can appropriately set the arrangement, the ratio, and the like of the normally driven sensor pixels PX and the refresh-driven sensor pixels PX according to the required resolution and the time required for the detection.

FIG. 8 is a sectional view schematically illustrating the adjacent photodiodes PD. In FIG. 8, the insulating films and the drive transistor Tr stacked between the substrate 21 and the photodiode PD (refer to FIG. 4) are not illustrated, but illustrated as a TFT layer 28.

As illustrated in FIG. 8, in the first photodiode PD1, the second photodiode PD2, and a third photodiode PD3 adjacent to one another in the first direction Dx, the lower electrodes 31 are arranged so as to be spaced apart to correspond to the photodiodes PD. The insulating film 36 is provided between the adjacent lower electrodes 31. The upper electrode 35 is provided continuously across the first photodiode PD1, the second photodiode PD2, and the third photodiode PD3.

During the first period T1 in which the outputs of the first and the third photodiodes PD1 and PD3 are detected, the first and the third photodiodes PD1 and PD3 are driven in the reverse bias state, and during the same first period T1, the second photodiode PD2 is driven in the forward bias state. More specifically, the power supply potential PVSS is supplied to the upper electrode 35 (anode) of the first photodiode PD1, the second photodiode PD2, and the third photodiode PD3.

During the first period T1, the reset potential VRST higher than the power supply potential PVSS is supplied to the lower electrode 31 (cathode) of the first photodiode PD1. The refresh potential VREF lower than the power supply potential PVSS is supplied to the lower electrode 31 (cathode) of the second photodiode PD2. The reset potential VRST higher than the power supply potential PVSS is supplied to the lower electrode 31 (cathode) of the third photodiode PD3.

During the second period T2 (refer to FIG. 6) in which the output of the second photodiode PD2 is detected, the first and the third photodiodes PD1 and PD3 are driven in the forward bias state, and during the same second period T2, the second photodiode PD2 is driven in the reverse bias state. During the second period T2, the power supply potential PVSS is supplied to the upper electrode 35 (anode) of the first photodiode PD1, the second photodiode PD2, and the third photodiode PD3.

During the second period T2, the refresh potential VREF lower than the power supply potential PVSS is supplied to the lower electrode 31 (cathode) of the first photodiode PD1. The reset potential VRST higher than the power supply potential PVSS is supplied to the lower electrode 31 (cathode) of the second photodiode PD2. The refresh potential VREF lower than the power supply potential PVSS is supplied to the lower electrode 31 (cathode) of the third photodiode PD3.

In the present embodiment, a vertical electric field is generated between the upper electrode 35 and the lower electrode 31 of each of the photodiodes PD, and different potentials (reset potential VRST and refresh potential VREF) are supplied to the adjacent lower electrodes 31, so that a fringe electric field indicated by an arrow F is generated.

As a result, during, for example, the first period T1, in the first and the third photodiodes PD1 and PD3 driven in the reverse bias state, carriers generated in the active layer 33 in an area overlapping the lower electrode 31 and carriers generated in the active layer 33 in an inter-pixel area 33a are attracted toward the lower electrode 31 of each of the first and the third photodiodes PD1 and PD3. Alternatively, some of the carriers generated in the active layer 33 in an area overlapping the lower electrode 31 of the second photodiode PD2 are also attracted toward the lower electrode 31 of each of the first and the third photodiodes PD1 and PD3. As a result, the detection device 1 can increase photocurrent that flows in the photodiode PD during the exposure period, thereby improving sensor sensitivity.

The following describes a hypothetical case where the adjacent photodiodes PD are driven in the reverse bias state. In this case, the same reset potential VRST is supplied to each of the adjacent lower electrodes 31, and no fringe electric field is generated. Therefore, the carriers generated in the active layer 33 in the inter-pixel area 33a may have a delayed response to reach the lower electrode 31, compared with carriers generated in the active layer 33 in the area overlapping the lower electrode 31.

In the present embodiment, since the fringe electric field is generated between the adjacent lower electrodes 31, the carriers generated in the active layer 33 in the inter-pixel area 33a also quickly move to the lower electrode 31. As a result, the detection device 1 can improve the response speed of the detection.

Although FIG. 6 illustrates the sensor pixels PX in three rows and three columns for ease of understanding the description, the present disclosure is not limited to such configuration. The drive patterns of the present embodiment can be applied to the sensor pixels PX in four or more rows and four or more columns. Although FIG. 6 illustrates the example in which the refresh-driven sensor pixels PX (photodiodes PD driven in the forward bias state) and the normally driven sensor pixels PX (photodiodes PD driven in the reverse bias state) are alternately arranged, the present disclosure is not limited to such configuration. The drive patterns of the refresh-driven sensor pixels PX (photodiodes PD driven in the forward bias state) and the normally driven sensor pixels PX (photodiodes PD driven in the reverse bias state) can be changed as appropriate.

### Second Embodiment

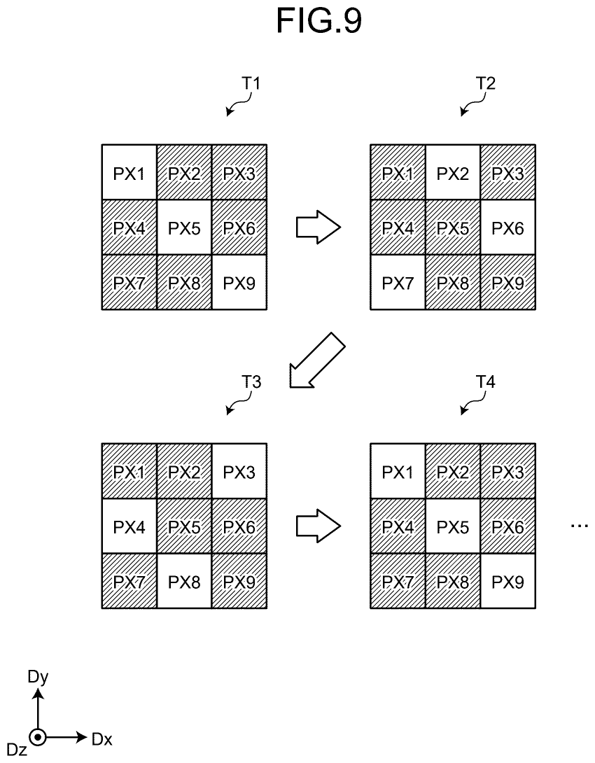

FIG. 9 is an explanatory diagram for explaining the drive patterns of the sensor pixels according to a second embodiment. In the second embodiment, as illustrated in FIG. 9, one normally driven sensor pixel PX and two refresh-driven sensor pixels PX are arranged in three sensor pixels PX arranged in the first direction Dx. In the same way, in the second direction Dy, one normally driven sensor pixel PX and two refresh-driven sensor pixels PX are arranged in three sensor pixels PX arranged in the second direction Dy. In other words, among three photodiodes PD arranged in the first direction Dx, one photodiode PD is driven in the reverse bias state and two photodiode PDs are driven in the forward bias state. In the same way, in the second direction Dy, among three photodiodes PD arranged in the second direction Dy, one photodiode PD is driven in the reverse bias state and two photodiode PDs are driven in the forward bias state.

Specifically, during the first period T1, each of the photodiodes PD in the sensor pixels PX1, PX5, and PX9 is driven in the reverse bias state, and the output from each of the photodiodes PD in the sensor pixels PX1, PX5, and PX9 is detected. During the first period T1, each of the photodiodes PD in the sensor pixels PX2, PX3, PX4, PX6, PX7, and PX8 is driven in the forward bias state, and each of the photodiodes PD in the sensor pixels PX2, PX3, PX4, PX6, PX7, and PX8 is refreshed.

During the second and the third periods T2 and T3, the positions of the sensor pixels PX driven in the reverse bias state (sensor pixels PX that detect outputs from the photodiodes PD) are sequentially shifted in the first direction Dx.

For example, focusing on the sensor pixels PX1, PX2, and PX3 in the first row, during the first period T1 in which the output of the first photodiode PD1 is detected, the first photodiode PD1 is driven in the reverse bias state, and the second and the third photodiodes PD2 and PD3 are driven in the forward bias state.

Then, during the second period T2 in which the output of the second photodiode PD2 is detected, the second photodiode PD2 is driven in the reverse bias state, and the first and the third photodiodes PD1 and PD3 are driven in the forward bias state.

During the third period T3 in which the output of the third photodiode PD3 is detected, the third photodiode PD3 is driven in the reverse bias state, and the first and the second photodiodes PD1 and PD2 are driven in the forward bias state. When a fourth period T4 starts, the drive pattern returns to that of the first period T1. Thus, the drive patterns of the first period T1 to the third period T3 are repeatedly executed.

In the present embodiment, the ratio of the number of the normally driven sensor pixels PX to the number of all the sensor pixels PX in each period is 1/3, and thus, the resolution is 1/3 the resolution in the case where all the sensor pixels PX are used for the detection. In the present embodiment, the period of the refresh driving can be made longer without decreasing the frame rate of the detection, compared with the first embodiment described above.

### Third Embodiment

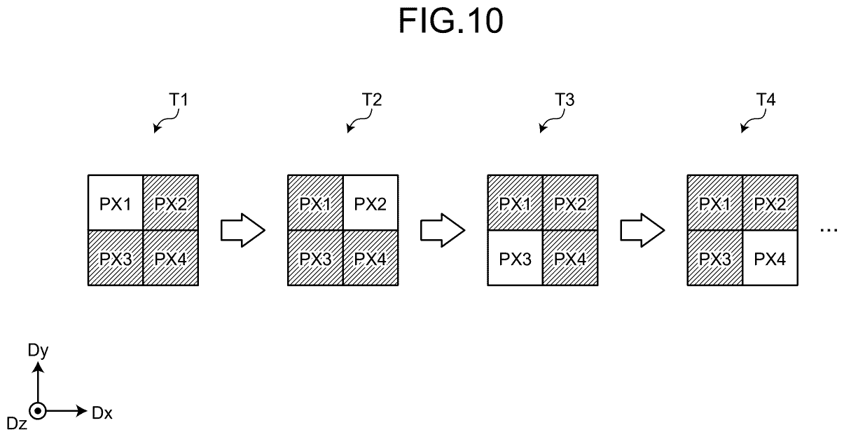

FIG. 10 is an explanatory diagram for explaining the drive patterns of the sensor pixels according to a third embodiment. In the third embodiment, the drive patterns of a total of the four sensor pixels PX in two rows and two columns will be described, as illustrated in FIG. 10. In the first row, the sensor pixels PX1 and PX2 are arranged in the first direction Dx. In the second row, the sensor pixels PX3 and PX4 are arranged in the first direction Dx.

During each period, the four sensor pixels PX (photodiodes PD) in two rows and two columns are arranged such that one normally driven sensor pixel PX and three refresh-driven sensor pixels PX are arranged. In other words, among the four photodiodes PD in two rows and two columns, one photodiode PD is driven in the reverse bias state, and the other three photodiodes PD are driven in the forward bias state, during each period.

During the first period T1, the first photodiode PD1 of the sensor pixel PX1 is driven in the reverse bias state, and the output from the first photodiode PD1 is detected. During the first period T1, each of the photodiodes PD of the sensor pixels PX2, PX3, and PX4 is driven in the forward bias state, and each of the photodiodes PD of the sensor pixels PX2, PX3, and PX4 is refreshed.

During the second period T2, the second photodiode PD2 of the sensor pixel PX2 is driven in the reverse bias state, and the output from the second photodiode PD2 is detected. During the second period T2, each of the photodiodes PD of the sensor pixels PX1, PX3, and PX4 is driven in the forward bias state, and each of the photodiodes PD of the sensor pixels PX1, PX3, and PX4 is refreshed.

During the third period T3, the third photodiode PD3 of the sensor pixel PX3 is driven in the reverse bias state, and the output from the third photodiode PD3 is detected. During the third period T3, each of the photodiodes PD of the sensor pixels PX1, PX2, and PX4 is driven in the forward bias state, and each of the photodiodes PD of the sensor pixels PX1, PX2, and PX4 is refreshed.

During the fourth period T4, the fourth photodiode PD4 of the sensor pixel PX4 is driven in the reverse bias state, and the output from the fourth photodiode PD4 is detected. During the fourth period T4, each of the photodiodes PD of the sensor pixels PX1, PX2, and PX3 is driven in the forward bias state, and each of the photodiodes PD of the sensor pixels PX1, PX2, and PX3 is refreshed. After the subsequent period starts, the drive pattern returns to that of the first period T1, and thereafter the drive patterns of the first period T1 to the fourth period T4 are repeatedly executed.

In the present embodiment, the ratio of the number of the normally driven sensor pixels PX to the number of all the sensor pixels PX in each period is 1/4, and thus, the resolution is 1/4 the resolution in the case where all the sensor pixels PX are used for the detection. In the present embodiment, the period of the refresh driving can be made longer without decreasing the frame rate of the detection compared with the first and the second embodiments described above.

### Fourth Embodiment

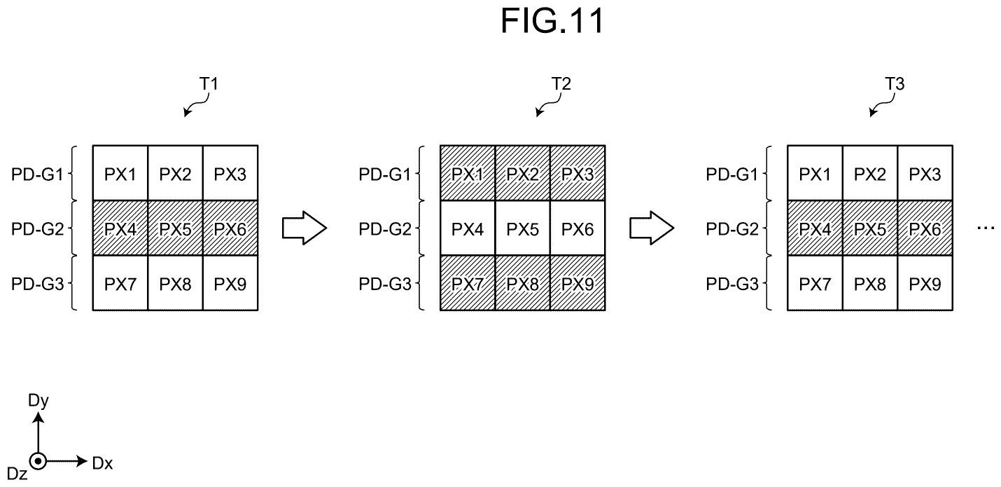

FIG. 11 is an explanatory diagram for explaining the drive patterns of the sensor pixels according to a fourth embodiment. In FIG. 11, the photodiodes PD included in the sensor pixels PX1, PX2, and PX3 in the first row are denoted as a “first photodiode group PD-G1”. The photodiodes PD included in the sensor pixels PX4, PX5, and PX6 in the second row are denoted as a “second photodiode group PD-G2”. The photodiodes PD included in the sensor pixels PX7, PX8, and PX9 in the third row are denoted as a “third photodiode group PD-G3”.

The first photodiode group PD-G1 and the second photodiode group PD-G2 are provided adjacent to each other in the second direction Dy. The second photodiode group PD-G2 and the third photodiode group PD-G3 are provided adjacent to each other in the second direction Dy. In the following description, the first photodiode group PD-G1, the second photodiode group PD-G2, and the third photodiode group PD-G3 will each be simply referred to as a “photodiode group PD-G” when need not be distinguished from one another.

In the fourth embodiment, the drive pattern of the sensor pixels PX is alternately switched row by row. During the first period T1, the sensor pixels PX in the odd-numbered rows are normally driven, and the sensor pixels PX in the even-numbered row are driven to be refreshed. That is, during the first period T1 in which the outputs of the first photodiode group PD-G1 and the third photodiode group PD-G3 are detected, the first photodiode group PD-G1 and the third photodiode group PD-G3 are driven in the reverse bias state, and the second photodiode group PD-G2 is driven in the forward bias state.

During the second period T2, the sensor pixels PX in the odd-numbered rows are driven to be refreshed, and the sensor pixels PX in the even-numbered row are normally driven. That is, during the second period T2 in which the outputs of the second photodiode group PD-G2 are detected, the second photodiode group PD-G2 is driven in the reverse bias state, and the first photodiode group PD-G1 and the third photodiode group PD-G3 are driven in the forward bias state.

When the third period T3 starts, the drive pattern returns to that of the first period T1. Thus, the drive patterns of the first period T1 and the second period T2 are repeatedly executed.

In the fourth embodiment, since the drive pattern of the sensor pixels PX is controlled row by row, the drive pattern of the sensor pixels PX need not be switched column by column, and the control of the drive pattern is easier than in the first to the third embodiments described above.

While the preferred embodiments of the present disclosure have been described above, the present disclosure is not limited to the embodiments described above. The content disclosed in the embodiments is merely an example, and can be variously modified within the scope not departing from the gist of the present disclosure. Any modifications appropriately made within the scope not departing from the gist of the present disclosure also naturally belong to the technical scope of the present disclosure. At least one of various omissions, substitutions, and changes of the components can be made without departing from the gist of the embodiments described above and the modifications thereof.

What is claimed is:

1. A detection device comprising:
a substrate;
a plurality of photodiodes in each of which a lower electrode, a lower buffer layer, an active layer, an upper buffer layer, and an upper electrode are stacked on the substrate in the order as listed;
a plurality of drive transistors corresponding to the photodiodes; and
a gate line that is coupled to gates of the drive transistors and extends in a first direction, wherein the photodiodes comprise a first photodiode and a second photodiode that are arranged adjacent to each other in the first direction,
the first photodiode is configured to be driven in a reverse bias state and the second photodiode is configured to be driven in a forward bias state during a first period in which an output of the first photodiode is detected, and
the second photodiode is configured to be driven in the reverse bias state and the first photodiode is configured to be driven in the forward bias state during a second period in which an output of the second photodiode is detected.

2. The detection device according to claim 1, wherein the photodiodes configured to be driven in the forward bias state and the photodiodes configured to be driven in the reverse bias state are alternately arranged in the first direction, and alternately arranged in a second direction intersecting the first direction.

3. The detection device according to claim 2, wherein a drive pattern of the photodiodes configured to be driven in the forward bias state and the photodiodes configured to be driven in the reverse bias state during the second period is an inverted pattern with respect to a drive pattern of the photodiodes configured to be driven in the forward bias state and the photodiodes configured to be driven in the reverse bias state during the first period.

4. The detection device according to claim 1, wherein
the lower electrodes are arranged so as to be spaced apart to correspond to the photodiodes, and
the lower buffer layer, the active layer, the upper buffer layer, and the upper electrode are provided continuously across the photodiodes.

5. The detection device according to claim 1, wherein
the upper electrode of the first photodiode and the second photodiode is configured to be supplied with a first potential, and
during the first period:
the lower electrode of the first photodiode is configured to be supplied with a third potential higher than the first potential; and
the lower electrode of the second photodiode is configured to be supplied with a second potential lower than the first potential.

6. The detection device according to claim 1, wherein
the photodiodes comprise a third photodiode adjacent to the first photodiode and the second photodiode in the first direction,
the first photodiode is configured to be driven in the reverse bias state and the second photodiode and the third photodiode are configured to be driven in the forward bias state during the first period in which the output of the first photodiode is detected,
the second photodiode is configured to be driven in the reverse bias state and the first photodiode and the third photodiode are configured to be driven in the forward bias state during the second period in which the output of the second photodiode is detected, and
the third photodiode is configured to be driven in the reverse bias state and the first photodiode and the second photodiode are configured to be driven in the forward bias state during a third period in which an output of the third photodiode is detected.

7. The detection device according to claim 1, wherein, among four photodiodes in two rows and two columns out of the photodiodes, one of the four photodiodes is configured to be driven in the reverse bias state, and three of the four photodiodes are configured to be driven in the forward bias state.

8. The detection device according to claim 1, wherein
anodes of the first photodiode and the second photodiode are configured to be supplied with a first potential,
a cathode of the second photodiode is configured to be supplied with a second potential lower than the first potential during the first period in which the output of the first photodiode is detected, and
a cathode of the first photodiode is configured to be supplied with the second potential during the second period in which the output of the second photodiode is detected.

9. The detection device according to claim 8, wherein
the cathode of the first photodiode is configured to be supplied with a third potential higher than the first potential during the first period in which the output of the first photodiode is detected, and
the cathode of the second photodiode is configured to be supplied with the third potential during the second period in which the output of the second photodiode is detected.

10. A detection device comprising:
a substrate;
a plurality of photodiodes in each of which a lower electrode, a lower buffer layer, an active layer, an upper buffer layer, and an upper electrode are stacked on the substrate in the order as listed;
a plurality of drive transistors corresponding to the photodiodes; and
a gate line that is coupled to a gate of the drive transistor and extends in a first direction, wherein
the photodiodes comprise a first photodiode group that comprises a plurality of the photodiodes arranged in the first direction and a second photodiode group that comprises a plurality of the photodiodes and is located adjacent to the first photodiode group in a second direction intersecting the first direction,
the first photodiode group is configured to be driven in a reverse bias state and the second photodiode group is configured to be driven in a forward bias state during a first period in which outputs of the first photodiode group are detected, and
the second photodiode group is configured to be driven in the reverse bias state and the first photodiode group is configured to be driven in the forward bias state during a second period in which outputs of the second photodiode group are detected.
